(19) United States
(12) Patent Application Publication
(10) Pub. No.: US 2024/0142276 A1
(43) Pub. Date: May 2, 2024

(54) BATTERY-FREE ROTATION DETECTING DEVICE

(71) Applicant: Industrial Technology Research Institute, Hsinchu (TW)

(72) Inventor: JUI-PING CHANG, Kaohsiung City (TW)

(21) Appl. No.: 18/120,002

(22) Filed: Mar. 10, 2023

(30) Foreign Application Priority Data
Nov. 1, 2022 (TW) 111141527

(51) Int. Cl. G01D 5/20

(52) U.S. Cl. CPC G01D 5/2013

(57) ABSTRACT

A battery-free rotation detecting device includes a rotatable carrier, a first magnetic element, a second magnetic element, a magnetic field shield and a detection coil set. The rotatable carrier has a rotation axis. The first magnetic element is located on the rotatable carrier and has a plurality of first magnetizing portions, and the magnetization directions of the first magnetizing portions are parallel to the rotation axis. The second magnetic element is spaced apart from the first magnetic element and has a plurality of second magnetizing portions. The magnetization directions of the second magnetizing portions are parallel to the rotation axis. The magnetic field shield located on the first magnetic element or the second magnetic element, is used to reduce the magnetic flux density between the first magnetic element and the second magnetic element. The detection coil set is located between the first magnetic element and the second magnetic element.

### CROSS REFERENCE TO RELATED APPLICATIONS

All related applications are incorporated by reference. The present application is based on, and claims priority from, Taiwan Application Serial Number 111141527, filed on Nov. 1, 2022, the disclosure of which is hereby incorporated by reference herein in its entirety.

### TECHNICAL FIELD

The disclosure relates to a rotation detecting device, and in particular relates to a battery-free rotation detecting device.

### BACKGROUND

With the development of automatic manufacturing technology, rotation devices are widely used in various applications such as motors, machine tools, optoelectronic process mechanical equipment, multi-axis robotic arm . . . etc. In these rotation devices, the rotation detectors are often installed to convert mechanical displacement into electrical signals through optoelectronic principles or electromagnetic principles to detect and monitor whether the rotating device is in operation, the rotation numbers or the rotating direction. The rotation detector, which is used to monitor, track and record the rotation numbers or the state of the rotating device, must maintain the rotation detection or monitoring function even when the external power supply is interrupted. As a result, it is required to carry a battery.

Therefore, the conventional rotation detectors must be inspected and the battery must be replaced periodically. The operation of the production line may have to be interrupted during the replacement, which affects the productivity and increases the maintenance cost. Moreover, with the trend of miniaturization of equipment such as machine tools and the increasing demand for high-density configurations of machines, a solution should be provided to meet the miniaturization design for the size and configuration of the rotation detector.

Regarding the conventional rotational detector, a configuration of adapting one detection coil and one magnetic sensor is provided. When the magnetic flux density strength exceeds the threshold value of the detection coil, a voltage pulse signal is then generated by the detection coil for counting the number of turns. However, when the clockwise/counterclockwise rotation crosses 0°, the output of the voltage pulse signal has the phase angle delay, which will result in a cross-turn counting blind angle (e.g., ±α°), and thus results in the chance of misjudgment of multi-turn update.

Furthermore, in order to determine the rotating direction, it is needed for the conventional rotation detectors to use the configuration of at least “two detection coils” or “one detection coil and a magnetic sensor.” The problems created from the above configuration are increased cost, complex back-end circuit design, and increased space requirements for arranging components.

Therefore, how to provide a “battery-free rotation detecting device” that not only reduces manufacturing and maintenance costs and time, but also meets the design requirements of miniaturization and reduces the chance of misjudgment of the turns number update, has become an issue to be solved by the industry.

### SUMMARY

A battery-free rotation detecting device is provided in the disclosure, including a rotatable carrier, a first magnetic element, a second magnetic element and a detection coil set. The rotatable carrier has a rotation axis. The first magnetic element is on the rotatable carrier and has a plurality of first magnetizing portions. Magnetization directions of the first magnetizing portions are parallel to the rotation axis, and a quantity of first magnetizing portions is a first number. The second magnetic element is on the rotatable carrier and spaced apart from the first magnetic element and has a plurality of second magnetizing portions. A quantity of the second magnetizing portions is a second number which is not equal to the first number. Magnetization directions of the second magnetizing portions are parallel to the rotation axis. The detection coil set is disposed between the first magnetic element and the second magnetic element. The rotatable carrier, the first magnetic element and the second magnetic element rotate synchronously. The detection coil set senses a change of magnetic flux density between the first magnetic element and the second magnetic element to generate an electrical signal.

A battery-free rotation detecting device is provided in the disclosure, including a rotatable carrier, a first magnetic element, a second magnetic element, a magnetic field shield and a detection coil set. The rotatable carrier has a rotation axis. The first magnetic element is on the rotatable carrier and has a plurality of first magnetizing portions. Magnetization directions of the first magnetizing portions are parallel to the rotation axis. The second magnetic element is spaced apart from the first magnetic element, having a plurality of second magnetizing portions. Magnetization directions of the second magnetizing portions are parallel to the rotation axis. The magnetic field shield is disposed on the first magnetic element or the second magnetic element for decreasing magnetic flux density between the first magnetic element and the second magnetic element. The detection coil set is disposed between the first magnetic element and the second magnetic element. The rotatable carrier, the first magnetic element and the second magnetic element rotate synchronously. The detection coil set senses a change of magnetic flux density between the first magnetic element and the second magnetic element to generate an electrical signal.

A detailed description is given in the following embodiments with reference to the accompanying drawings, in order to make the disclosure more comprehensible.

### BRIEF DESCRIPTION OF THE DRAWINGS

FIG. 1A is a schematic diagram of a battery-free rotating detecting device according to an embodiment of the disclosure.

FIG. 1B is a schematic diagram of a battery-free rotating detecting device according to another embodiment of the disclosure.

FIG. 2 is a schematic diagram of a detection coil set according to an embodiment of the disclosure.

FIG. 3 is a schematic diagram illustrating the curves of the magnetic flux density and the electrical signal according to an embodiment of the disclosure.

FIG. 4 is a schematic diagram of a battery-free rotating detecting device according to another embodiment of the disclosure.

FIG. 5 is a schematic diagram illustrating the curves of the magnetic flux density and the electrical signal according to another embodiment of the disclosure.

FIG. 6 is a schematic diagram illustrating a comparison of the magnetic flux density curves between an embodiment of the disclosure and the conventional technology.

FIG. 7 is a schematic diagram illustrating a comparison of the angles of the cross-turn counting blind area between an embodiment of the disclosure and the conventional technology.

FIG. 8 is a flow chart for counting the number of rotational revolutions according to an embodiment of the disclosure.

### DETAILED DESCRIPTION

In order to clearly and conveniently illustrating the drawings, the components in the drawings may be presented enlarged or reduced in size and scale. In the following detailed description and/or claims, when a component is referred to as being “connected” or “coupled” to another component, it can be directly connected or coupled to the other component or through an intermediate component. When a component is referred to as being “directly connected” or “directly coupled” to another component, there is no intermediate component. Other words used for describing the relationship between components or layers should be interpreted in the same way. Ordinal numbers, such as “first” and “second,” have no sequential relationship with each other, and they are merely used to mark and distinguish two different elements having the same name. To facilitate understanding, the same components in the following embodiments are designated with the same symbols.

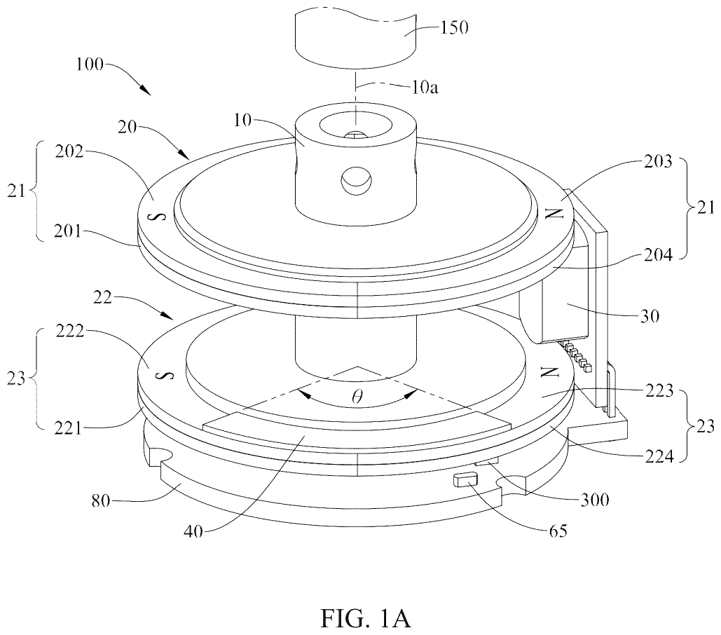

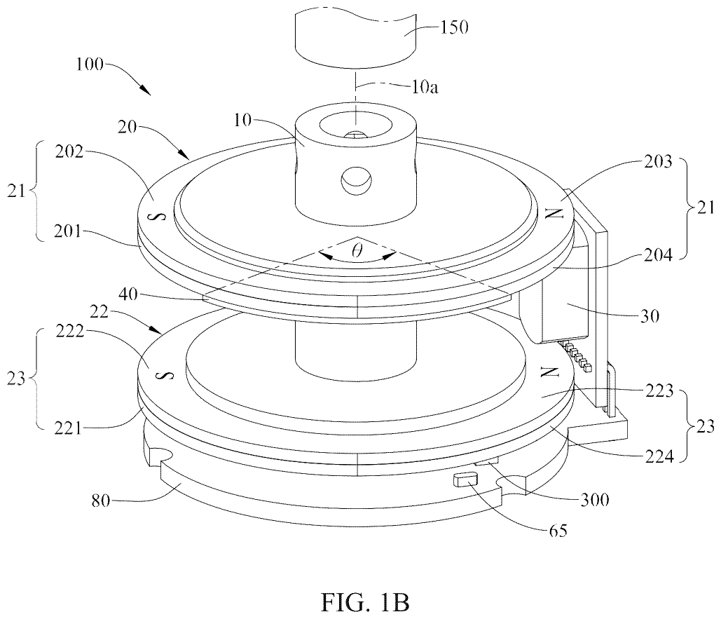

First, please refer to FIG. 1A. FIG. 1A is a schematic diagram of a battery-free rotation detecting device according to an embodiment of the disclosure. The battery-free rotation detecting device 100 can be combined with the rotation element 150, and it can include: a rotatable carrier 10, a first magnetic element 20, a second magnetic element 22, and a detection coil set 30. The battery-free rotation detecting device 100 mainly performs the detection and the monitor on that whether the rotation element 150 is operated or not.

The rotatable carrier 10 can be assembled or docked with the rotation element 150. The rotatable carrier 10 can be driven by the rotation element 150 such that the rotatable carrier 10, the first magnetic element 20 and the second magnetic element 22 can rotate synchronously. The rotatable carrier 10 is substantially of a cylindrical structure. The rotatable carrier 10 has a rotation axis 10a, and it can rotate clockwise or counterclockwise along the rotation axis 10a according to the rotation direction of the rotation element 150. In fact, the rotation element 150 may be, for example, a motor, a servo motor, or a brushless motor.

The first magnetic element 20 is located on the rotatable carrier 10. More specifically, the inner edge of the first magnetic element 20 is embedded on one end of the rotatable carrier 10. The first magnetic element 20 is substantially in the shape of a disc (but is not limited thereto, and may also be in other geometric shapes). The first magnetic element has a plurality of first magnetizing portions 21 which are axially magnetized. Each first magnetized portion 21 is composed of an N pole and an S pole. The N pole 201 and the S pole 202 form a single first magnetizing portion 21, and the N pole 203 and the S pole 204 form another first magnetizing portion 21. The magnetization direction of the first magnetizing portion 21 is parallel to the rotation axis 10a.

The second magnetic element 22 is located on the rotatable carrier 10. More specifically, the inner edge of the second magnetic element 22 is embedded on another end of the rotatable carrier 10. The second magnetic element 22 is substantially in the shape of a disc, but it is not limited thereto and may also be in other geometric shapes. The second magnetic element 22 has a plurality of second magnetizing portions 23 which are axially magnetized. Each second magnetized portion 23 is composed of an N pole and an S pole. The N pole 221 and the S pole 222 form a single second magnetizing portion 23, and the N pole 223 and the S pole 224 form another second magnetizing portion 23. The magnetization direction of the second magnetizing portion 23 is parallel to the rotation axis 10a.

The magnetization directions of any two adjacent ones of the first magnetizing portions are opposite, and the magnetization directions of any two adjacent ones of the second magnetizing portions are opposite. For example, the first magnetized portion 21 composed of the N pole 201 and the S pole 202 is adjacent to the first magnetized portion 21 composed of the N pole 203 and the S pole 204, but the magnetization directions are opposite. The second magnetized portion 23 composed of the S pole 222 and the N pole 221 is adjacent to the second magnetized portion 23 composed of the S pole 224 and the N pole 223, but the magnetization directions are opposite.

The first magnetizing portions 21 are arranged around the rotation axis 10a, the second magnetizing portions 23 are arranged around the rotation axis 10a, and the magnetization directions of the first magnetizing portions 21 and the second magnetizing portions at the same angle with respect to the rotation axis 10a are the same. More specifically, the first magnetizing portion 21 composed of the N pole 201 and the S pole 202 corresponds to the second magnetizing portion 23 composed of the N pole 221 and the S pole 222. In other words, the N pole 201 of the first magnetic element 20 and the N pole 221 of the second magnetic element 22 are disposed at the same angle with respect to the rotation axis 10a. The S pole 202 of the first magnetic element 20 and the S pole 222 of the second magnetic element 22 are disposed at the same angle with respect to the rotation axis 10a. For example, the N pole 201 and the S pole 202 of the first magnetized portion 21 of the first magnetic element are located at a position of 0° to 180° with respect to the rotation axis 10a, and the N pole 221 and the S pole 222 of the second magnetized portion 23 of the second magnetic element 22 are respectively located at positions of 180° to 360° with respect to the rotation axis 10a.

In the same way, the magnetization directions of the first magnetizing portion 21 composed of the N pole 203 and the S pole 204 of the first magnetic element 20 and the second magnetizing portion 23 composed of the N pole 223 and the S pole 224 of the second magnetic element 22 are the same. Additionally, the area of the first magnetic element 20 is substantially equal to the area of the second magnetic element 22. The second magnetic element 22 is located in the range of the orthographic projection of the first magnetic element along the rotation axis 10a. Moreover, the number of the first magnetizing portions 21 on the first magnetic element 20 of the disclosure is equal to the number of the second magnetizing portions 23 on the second magnetic element 22, and the number of magnetizing portions can be adjusted based on actual needs.

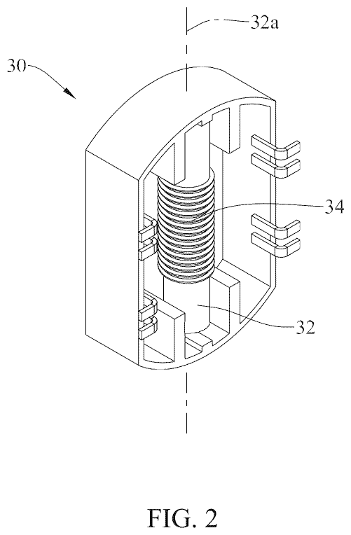

The detecting coil set 30 is located between the first magnetic element 20 and the second magnetic element 22, and it is installed on the circuit board 80. More specifically, the detection coil set 30 is located within the range of the orthographic projection of the first magnetic element 20 along the rotation axis 10a. The detection coil set 30 is a composite material capable of producing a large Barkhausen effect, and it includes a composite magnetic wire 32 (e.g., Wiegand wire) and a pick-up coil 34. Further referring to FIG. 2, it is a schematic diagram of a detection coil set according to an embodiment of the disclosure. The detection coil set 30 extends surrounding the coil axis 32a, and the coil axis 32a is parallel to the rotation axis 10a. The composite magnet wire 32 passes through the interior of the pick-up coil 34 without electrically contacting each other. The coil axis 322 can also be the central axis of the composite magnetic wire 32.

When the detection coil set 30 senses the change of the magnetic flux density between the first magnetic element 20 and the second magnetic element 22, the detection coil set 30 generates an electric signal. More specifically, when the first magnetic element 20 and the second magnetic element 22 are driven by the rotation element 150 to rotate, the first magnetic element 20 and the second magnetic element 22 can spin with respect to the detection coil set 30, so that the magnetic flux density between the first magnetic element 20 and the second magnetic element 22 through the detection coil set 30 varies. Accordingly, for each rotating revolution of the rotation element 150, the detection coil set 30 generates a sensed electric signal corresponding to the change of the induced magnetic flux density.

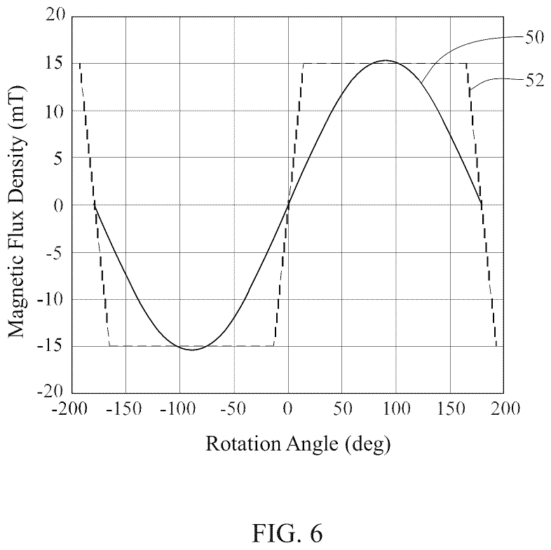

It should be specified that the rotation axis 10a and the coil axis 32a of the embodiment are parallel to each other. Since the detection coil set 30 is installed between the first magnetic element 20 and the second magnetic element 22, it can provide the feature of easy installation. The space between the first magnetic element 20 and the second magnetic element 22 are effectively utilized by the embodiment to meet the requirement of small-size design. In addition, this embodiment uses the structure of an axially magnetized dual magnet, which not only provides excellent magnetic flux density uniformity, but also enables the magnetic flux density curve to be trapezoidal (as shown in FIG. 6) to improve the problem of phase angle delay.

The magnetic field shield 40 is disposed on the first magnetic element 20 or the second magnetic element 22. More specifically, the magnetic field shield 40 is fixed to the surface of the first magnetic element 20 or the second magnetic element 22, and it is located between the first magnetic element 20 and the second magnetic element 22. The magnetic field shield 40 is used to reduce the magnetic flux density between the first magnetic element and the second magnetic element 22. Alternatively, the magnetic field shield 40 is used to cause the absolute value of the magnetic flux density between the first magnetic element 20 and the second magnetic element 22 to be less than a flux threshold value. More specifically, an induced magnetic field is formed between the first magnetic element 20 and the second magnetic element 22, the induced magnetic field is positioned at an angle of +180° and −180° relative to the rotary axis 10a, and the magnetic flux density of the first magnetic element 20 or the second magnetic element 22 is reduced by the magnetic field shield 40. The magnetic field shield 40 is a fan-shaped sheet structure, and the centroid angle θ of the magnetic field shield 40 is equal to 5°. In another embodiment, the centroid angle θ of the magnetic field shield 40 may be greater than 5°.

In one embodiment, the magnetic field shield 40 is positioned on the first magnetic element 20 and covers a portion of the first magnetic element 20 (as shown in FIG. 1B). In particular, the magnetic field shield 40 is used to shield the intersection of the two adjacent first magnetizing portions 21. For example, the magnetic field shield 40 shields the intersection of the S pole 204 of the first magnetizing portion 21 and the N pole 201 of another adjacent first magnetizing portion 21. The area of the S pole 204 of the first magnetizing portion 21 shielded by the magnetic field shield 40 may be equal to the area of the N pole 201 of another adjacent first magnetizing portion 21 shielded by the magnetic field shield 40.

In other embodiments (as shown in FIG. 1A), the magnetic field shield 40 is disposed on the second magnetic element 22 and covers a portion of the second magnetic element 22, wherein the magnetic field shield 40 is used to shield the intersection of two adjacent second magnetizing portions 23. For example, the magnetic field shield 40 shields the intersection of the N pole 223 of the second magnetizing portion 23 and the S pole 222 of another adjacent second magnetizing portion 23, and the area of the N pole 223 of the second magnetizing portion 23 shielded by the magnetic field shield 40 may be equal to the area of the S pole 222 of another adjacent second magnetizing portion 23 shielded by the magnetic field shield 40. In one embodiment, the magnetic field shield 40 is positioned on the second magnetic element 22, and it covers a portion of the second magnetic element 22. In particular, the magnetic field shield 40 is used to shield the intersection of two adjacent second magnetizing portions 23 and cover a portion of the two adjacent second magnetizing portions 23.

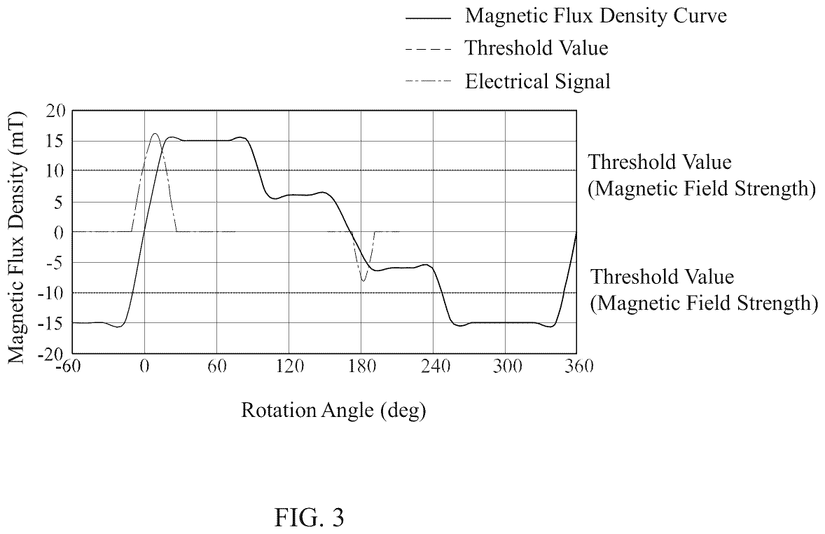

Next, please refer to FIG. 3, which is a schematic diagram illustrating the curves of the magnetic flux density and the electrical signal according to an embodiment of the disclosure. The induction magnetic field formed between the first magnetic element 20 and the second magnetic element 22 serves as the applied magnetic field of the detection coil set 30. As shown in FIG. 3, whenever the direction of the applied magnetic field is reversed, the internal magnetic poles of the detection coil set 30 also flip instantaneously and generate an electrical signal output according to Faraday's law. The magnitude of the electrical signal is related to the strength of the applied magnetic field. For example, when the magnetic flux density curve of the applied magnetic field is larger than or equal to the positive threshold value (10 mT) or smaller than the negative threshold value (−10 mT), the detection coil set 30 generates a signal output of +5˜+10V or −5˜−10V. In other words, if the applied magnetic field is between −10˜10 mT, the detection coil set 30 can generate the positive voltage signal of +1˜+5V or the negative voltage signal output of −1˜−5V. When the magnetic flux density curve is less than or equal to the negative voltage threshold value, the detection coil set 30 generates an electrical signal output of 1˜5V. The back-end circuit (such as the rectifier voltage-regulation circuit 300 and operation circuit 65) also has threshold values, such as the positive voltage threshold value (max-V) and the negative voltage threshold value (min-V). When the electrical signal is higher than the positive voltage threshold value (max-V) or lower than the negative voltage threshold value (min-V) will the number of turns be increased or decreased by one. For example, the positive voltage threshold value (max-V) and the negative voltage threshold value (min-V) can be 5V or −5V respectively. The back-end circuit will add one turn when the electrical signal is higher than 5V, and subtract one turn when the electrical signal is lower than −5V. Therefore, single coil is required for the above mechanism to determine the direction of rotation and the number of rotating revolutions.

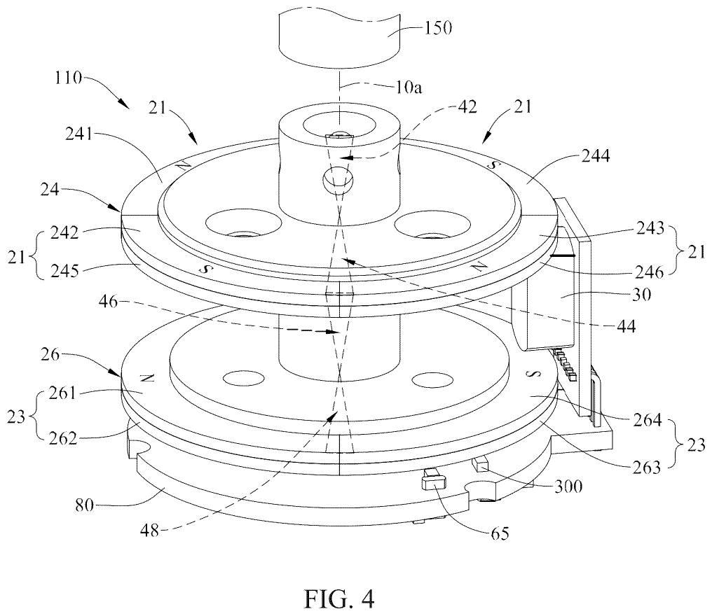

Afterwards, please refer to FIG. 4, which is a schematic diagram of the battery-free rotating detecting device of another embodiment of the disclosure. The battery-free rotating detecting device 110 can be combined with a rotation element 150 and include: a rotatable carrier 10, a first magnetic element 24, a second magnetic element 26, and a detection coil set 30. The details of the rotatable device 10 and the detection coil set 30 in the embodiment are similar to the embodiment shown in FIG. 1A and will not be described hereinafter. The embodiment of FIG. 4 differs from the embodiment of FIG. 1A in that the magnetic field shield 40 is omitted in the embodiment of FIG. 4.

The first magnetic element 24 is disposed on the rotatable carrier 10. More specifically, the inner edge of the first magnetic element 24 is embedded in one end of the rotatable device 10. The first magnetic element 24 is substantially disc shaped (but could be other geometrical shapes without limitation). The quantity of the first magnetizing portions 21 of the first magnetic element 24 is the first number. As illustrated in the figure, the first magnetic element 24 has four axially magnetized first magnetizing portions 21 arranged around the rotary axis 10a, so that the first number in the embodiment is equal to four. The magnetization direction of each first magnetizing portion 21 is parallel to the rotary axis 10a, and it consists of one N pole and one S pole overlapping in the direction parallel to the rotary axis 10a. The two adjacent first magnetizing portions 21 have opposite magnetization directions. Namely, one of two adjacent first magnetizing portions 21 of the upper layer is the N pole, and the other one is the S pole, so that the first magnetizing portions 21 with different magnetization directions are staggered with each other. In this embodiment, the first magnetic element 24 of the upper layer is composed of the N pole 241, the S pole 242, the N pole 243 and the S pole 244, while the first magnetic element 24 of the lower layer is composed of the opposite poles of the aforementioned magnetic ones and overlaps below the upper layer. For example, as shown in FIG. 4, the N pole 245 of the first magnetic element 24 of the lower layer is located below the S pole 242, and the S pole 246 thereof is located below the N pole 243.

The second magnetic element 26 is disposed on the rotatable carrier 10. More specifically, the inner edge of the second magnetic element 26 is embedded in another end of the rotatable 10. The second magnetic element 26 is substantially disc shaped, but may be other geometrical shapes without limitation. The quantity of the second magnetizing portions 23 second magnetic element 26 is the second number. As shown in the figure, the second magnetic element 26 has two axially magnetized second magnetizing portions 23 arranged around the rotary axis 10a, so that the second number in the embodiment is equal to two. The magnetization direction of each second magnetizing portion 23 is parallel to the rotary axis 10a, and it consists of one N pole and one S pole overlapping in the direction parallel to the rotary axis 10a. Each second magnetizing portion 23 has a magnetization direction parallel to the rotary axis 10a and consists of an N pole and an S pole overlapping in the direction of the parallel rotary axis 10a. The two adjacent second magnetizing portions 23 have opposite magnetization directions. Namely, one of two adjacent second magnetizing portions 23 is the N pole, and the other one is the S pole, so that the second magnetizing portions 23 with different magnetization directions are staggered with each other. In this embodiment, the second magnetic element 26 of the upper layer is composed of the N pole 261 and the S pole 264, while the second magnetic element 26 of the lower layer is composed of the opposite poles of the aforementioned magnetic ones and overlaps below the upper layer. For example, as shown in FIG. 4, the S pole 262 of the second magnetic element 26 of the lower layer is located below the N pole 261, and the N pole 263 thereof is located below the S pole 264. The first number is not equal to the second number. In the embodiment, the first number is greater than the number of the second number. The first number of the first magnetizing portion 21 of the first magnetic element 24 is two times of the second number of the second magnetizing portion 23. In some embodiments, the first number can be smaller than the second number. For example, the first number of the first magnetization portion 21 may be half of the second number of the second magnetization portion 23. In other words, the first number is smaller than the second number.

In addition, the first magnetic element 24 further includes a first head transition zone 42 and a first tail transition zone 44 located at the intersection of the first magnetizing portion 21, with an angle of 180° between the first head transition zone 42 and the first tail transition zone 44 with respect to the rotation axis 10a. The second magnetic element 26 also includes a second head transition zone 46 and a second tail transition zone 48 located at the intersection of the second magnetizing portions 23. The second head transition zone 46 is at the same angle as the first transition zone 42 with respect to the rotation axis 10a. The second tail transition zone 48 is positioned at the same angle as the first tail transition zone 44 with respect to the rotary axis 10a.

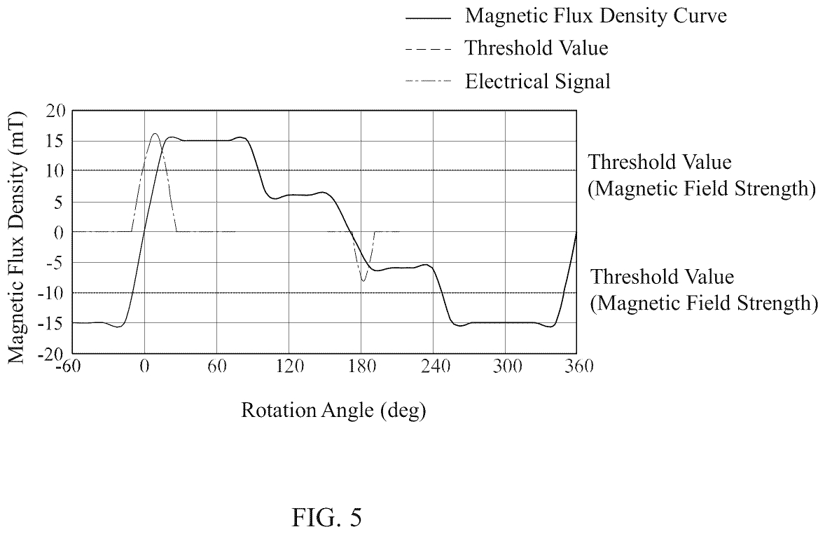

The magnetic flux density between the first magnetic element 24 and the second magnetic element 26 varies according to angle with respect to the rotation axis and the distribution of the magnetic flux density forms a change curve (as shown in FIG. 5). The slope of a segment corresponding to the first head transition zone 42 and the second head transition zone 46 of the change curve is greater than or equal to three. For example, the slope of another segment corresponding to the rotation angle of approximately +5° and −5° is greater than or equal to three. The slope of another segment of the change curve corresponding to the first tail transition zone 44 and the second tail transition zone 48 is less than zero and greater than −2.5. For example, the slope of the segment of the change curve corresponding to the rotation angle of approximately +185° and +175° is less than zero and greater than −2.5. The magnetic flux density illustrated in the change curve is in the unit of millitesla (corresponding to the vertical axis of FIG. 5), and the angle illustrated in the change curve is in the unit of degree angle (corresponding to the horizontal axis of FIG. 5).

Afterwards, please refer to FIG. 5, which illustrates the schematic curve of the magnetic flux density and the electrical signal according to another embodiment of the disclosure. Similarly, comparing FIG. 5 with FIG. 3, both of them have the same/similar change curves of the magnetic flux density versus the angle, which will not repeated here.

Referring to FIG. 6, it represents a schematic diagram illustrating a comparison of the magnetic flux density curves between an embodiment of the disclosure and the conventional technology. As shown in FIG. 6, the magnetic flux density curve 50 belongs to the conventional technology, and the magnetic flux density curve 52 belongs to the proposed technology of the disclosure. In comparison, the magnetic flux density curve 52 of the disclosure can produce a square wave-like magnetic flux density curve, which maximizes the magnetic flux density gradient (mT/deg) at 0° and reduces the phase angle delay, so as to avoid the situation that the output of the electrical signal drops because the magnetic flux density gradient is too large.

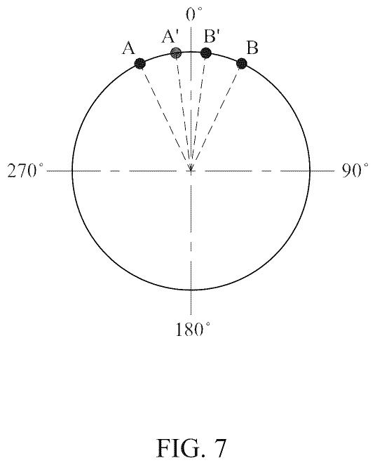

Please refer to FIG. 7, which illustrates the schematic comparison of the angles of the cross-turn counting blind area between an embodiment of the disclosure and the conventional technology. As shown in FIG. 7, the range A-B of the cross-turn counting blind area belongs to the conventional technology, and the range A′-B′ of the cross-turn counting blind area belongs to the disclosed technology. In comparison, the disclosure has a smaller cross-turn counting blind area. Since this disclosure can reduce the phase angle delay, it can effectively decrease the blind-area angle by more than 50% and reduce the chance of misjudgment of the turn-number update.

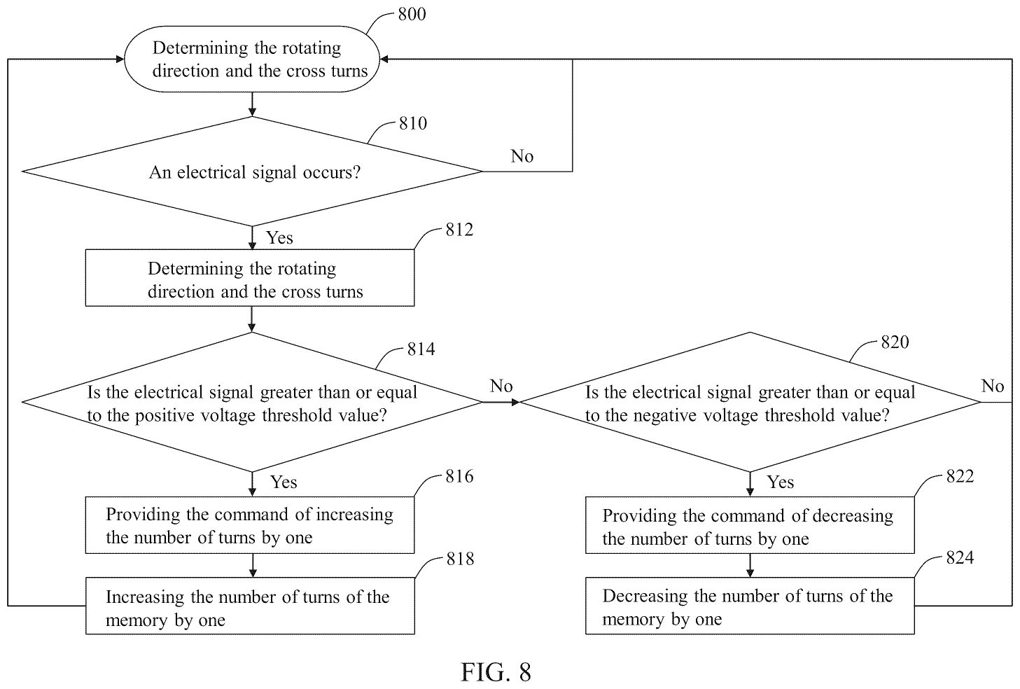

Please refer to FIG. 8, it is a flow chart for counting the number of rotational revolutions according to an embodiment of the disclosure. As shown in FIG. 8, the counting process of the rotational revolution of the embodiment includes the following steps:

In step S800, the status machine is idle, and step S810 is operated.

In step S810, it is checked whether the detection coil set 30 has an electrical signal output. If not, step S812 will be operated. In this step, when the first magnetic element 20 and the second magnetic element 22 are driven by the rotation element 150 and rotate with respect to the detection coil set 30, the polarity of the magnetic field changes between the first magnetic element 20 and the second magnetic element 22 through the detection coil set 30, and the change of the magnetic flux density of the detection coil set 30 can be detected to generate the corresponding electrical signal. Afterwards, the back-end circuit can detect and confirm whether the electrical signal is generated.

In step S812, the determination procedure for rotating direction and cross turns is performed, and step S814 is operated. In this step, the back-end circuit can determine the rotating direction and the number of turnings of the rotation element 150 based on the aforementioned electrical signal.

In step S814, it is checked whether the electrical signal outputted from the detection coil set 30 is greater than or equal to the positive voltage threshold value. If not, step S820 will be operated. If yes, step S816 will be operated. In this step, the rotating direction (clockwise or counterclockwise) and the number of rotating turns of the rotation element 150 can be determined by the back-end circuit determines based on the positive voltage threshold value of the comparator in its computing circuit 65. If the electrical number is higher than the positive voltage threshold value will the number of turns be added by one.

In step S816, the command of increasing the number of turns by one is provided, and step S818 is operated. In this step, the back-end circuit determines that the electrical signal is greater than the aforementioned positive voltage threshold value (e.g., 5V) and that the rotating direction of the rotation element 150 is clockwise rotation, and the back-end circuit can submit the command of increasing the number of turns by one.

In step S818, after the number of turns is added by one, it returns to step S800. For example, when it is rotated clockwise, if the electric signal is greater than or equal to the positive voltage threshold value (for example, 5V) of the comparator in the operation circuit 65, the number of updated turns is increased by one. In this step, the memory updates that the number of turns is added by one after the back-end circuit issues the command of increasing the number of turns by one.

In step S820, it is checked whether the electrical signal outputted from the detection coil set 30 is less than or equal to the negative voltage threshold value. If not, it returns to step S800. If yes, step S822 will be operated. In this step, the rotating direction (clockwise or counterclockwise) and the number of rotating turns of the rotation element 150 can be determined by the back-end circuit determines based on the negative voltage threshold value of the comparator in its computing circuit 65. If the electrical number is less than the negative voltage threshold value will the number of turns be decreased by one.

In step S822, the command of decreasing the number of turns by one is provided, and step S824 is operated. In this step, the back-end circuit determines that the electrical signal is less than the aforementioned negative voltage threshold value (e.g., −5V) and that the rotating direction of the rotation element 150 is counterclockwise rotation, and the back-end circuit can submit the command of decreasing the number of turns by one.

In step S824, after the number of turns is decreased by one, it returns to step S800. In this step, the memory updates that the number of turns is decreased by one after the back-end circuit issues the command of decreasing the number of turns by one.

In comparison of the rotation number counting process of the embodiment and the conventional technology, the procedure of reading from the memory is eliminated, and the operation procedure of the rotation number counting is simpler and faster.

Based on the foregoing, it requires single detection coil set to determine the rotation direction by the battery-free rotation detecting device of the disclosure. In association with the axially magnetized magnetic elements, the magnetic flux density curve appears trapezoidal, which can effectively improve the problem of phase angle delay.

Based on the design of the first magnetic element, the second magnetic element, the magnetic field shield and the detection coil set of the embodiment of the disclosure, the cross-turn blind are can be reduced by more than 50%, and the chance of misjudgment for the update of the turns number can be decreased, which can relatively improve the accuracy of the update of the turns number.

The rotatable device of the embodiment of the disclosure can be directly integrated with the devices having the rotational motions, such as encoders, bicycles, smart water meters, and wireless charging devices. By generating power for the back-end circuit by the magnetic device and the detection coil set, no additional power supply or battery backup is required to reduce the maintenance manpower, time and cost.

Although the disclosure has been disclosed in terms of the embodiments, it is not intended to limit this disclosure. Any person with general knowledge in the field of technology to which this disclosure belongs may, within the spirit and scope of the disclosure, make some amendments and modifications. Therefore, the protection scope of the disclosure shall be subject to the scope defined by the patent application attached hereto.

What is claimed is:

1. A battery-free rotation detecting device, comprising:
a rotatable carrier, having a rotation axis;
a first magnetic element, on the rotatable carrier, having a plurality of first magnetizing portions, wherein magnetization directions of the first magnetizing portions are parallel to the rotation axis, and a quantity of first magnetizing portions is a first number;
a second magnetic element, on the rotatable carrier and spaced apart from the first magnetic element, having a plurality of second magnetizing portions, wherein a quantity of the second magnetizing portions is a second number which is not equal to the first number, and magnetization directions of the second magnetizing portions are parallel to the rotation axis; and
a detection coil set, disposed between the first magnetic element and the second magnetic element;
wherein the rotatable carrier, the first magnetic element and the second magnetic element rotate synchronously, and the detection coil set senses a change of magnetic flux density between the first magnetic element and the second magnetic element to generate an electrical signal.

2. The battery-free rotation detecting device as claimed in claim 1, wherein the first number is two times of the second number or half the second number.

3. The battery-free rotation detecting device as claimed in claim 1, wherein the first number is greater than the second number.

4. The battery-free rotation detecting device as claimed in claim 1, wherein the first number is less than the second number.

5. The battery-free rotation detecting device as claimed in claim 1, wherein the detection coil set comprises a composite magnetic wire and a pickup coil.

6. The battery-free rotation detecting device as claimed in claim 1, wherein magnetization directions of any two adjacent ones of the first magnetizing portions are opposite, and magnetization directions of any two adjacent ones of the second magnetizing portions are opposite.

7. The battery-free rotation detecting device as claimed in claim 1, wherein the first magnetizing portions are arranged around the rotation axis, and the second magnetizing portions are arranged around the rotation axis.

8. The battery-free rotation detecting device as claimed in claim 1, wherein the first magnetic element further comprises a first head transition zone and a first tail transition zone located at intersection of the first magnetizing portions, with an angle of 180° between the first head transition zone and the first tail transition zone with respect to the rotation axis, and the second magnetic element comprises a second head transition zone and a second tail transition zone located at intersection of the second magnetizing portions, the second head transition zone and the first head transition zone are at the same angle with respect to the rotation axis, and the second tail transition zone and the first tail transition zone are at the same angle with respect to the rotation axis.

9. The battery-free rotation detecting device as claimed in claim 8, wherein magnetic flux density between the first magnetic element and the second magnetic element varies according to angle with respect to the rotation axis and a distribution of the magnetic flux density forms a change curve, slope of a segment of the change curve corresponding to the first head transition zone and the second head transition zone is greater than or equal to three, slope of another segment of the change curve corresponding to the first tail transition zone and the second tail transition zone is less than zero and greater than −2.5, magnetic flux density illustrated by the change curve is in unit of millitesla, and angle illustrated by the change curve is in unit of degree angle.

10. A battery-free rotation detecting device, comprising:
a rotatable carrier, having a rotation axis;
a first magnetic element, on the rotatable carrier, having a plurality of first magnetizing portions, wherein magnetization directions of the first magnetizing portions are parallel to the rotation axis;
a second magnetic element, spaced apart from the first magnetic element, having a plurality of second magnetizing portions, wherein magnetization directions of the second magnetizing portions are parallel to the rotation axis;
a magnetic field shield, disposed on the first magnetic element or the second magnetic element, for decreasing magnetic flux density between the first magnetic element and the second magnetic element; and
a detection coil set, disposed between the first magnetic element and the second magnetic element;
wherein the rotatable carrier, the first magnetic element and the second magnetic element rotate synchronously, and the detection coil set senses a change of magnetic flux density between the first magnetic element and the second magnetic element to generate an electrical signal.

11. The battery-free rotation detecting device as claimed in claim 10, wherein the magnetic field shield is on the first magnetic element, and covers a portion of the first magnetic element.

12. The battery-free rotation detecting device as claimed in claim 10, wherein the magnetic field shield is at intersection of two adjacent first magnetizing portions and covers a portion of the two adjacent first magnetizing portions.

13. The battery-free rotation detecting device as claimed in claim 10, wherein the magnetic field shield is on the second magnetic element, and covers a portion of the second magnetic element.

14. The battery-free rotation detecting device as claimed in claim 10, wherein the magnetic field shield is at intersection of two adjacent second magnetizing portions and covers a portion of the two adjacent second magnetizing portions.

15. The battery-free rotation detecting device as claimed in claim 10, wherein the magnetic field shield is a fan-shaped sheet structure.

16. The battery-free rotation detecting device as claimed in claim 10, wherein centroid angle of the magnetic field shield is equal to or greater than 5°.

17. The battery-free rotation detecting device as claimed in claim 10, wherein the detection coil set comprises a composite magnetic wire and a pickup coil.

18. The battery-free rotation detecting device as claimed in claim 10, wherein magnetization directions of any two adjacent ones of the first magnetizing portions are opposite, and magnetization directions of any two adjacent ones of the second magnetizing portions are opposite.

19. The battery-free rotation detecting device as claimed in claim 10, wherein the number of the first magnetizing portions is equal to the number of the second magnetizing portions.

20. The battery-free rotation detecting device as claimed in claim 10, wherein the first magnetizing portions are arranged around the rotation axis, the second magnetizing portions are arranged around the rotation axis, and magnetization directions of the first magnetizing portions and the second magnetizing portions at the same angle with respect to the rotation axis are the same.
